(19) United States
(12) Patent Application Publication
(10) Pub. No.: US 2003/0116091 A1
(43) Pub. Date: Jun. 26, 2003

(54) Chemical vapor deposition vaporizer

(75) Inventors: Robert W. Grant, Hershey, PA (US); Larry D. McMillan, Colorado Springs, CO (US)

Correspondence Address: PATTON BOGGS, PO BOX 270930, LOUISVILLE, CO, 80027, US

(73) Assignee: Primaxx, Inc., Allentown, PA

(21) Appl. No.: 10/310,352

(22) Filed: Dec. 4, 2002

Related U.S. Application Data
(60) Provisional application No. 60/337,637, filed on Dec. 4, 2001.

(51) Int. Cl. C23C 16/00

(52) U.S. Cl. 118/726; 427/248.1

(57) ABSTRACT

A Chemical Vapor Deposition (CVD) vaporizer comprising: a liquid supply assembly having an environment supporting a liquid state for a plurality of precursor components of a liquid precursor blend; a venturi operative to atomize said liquid precursor blend; a vaporization chamber, located proximate to said liquid supply assembly and said venturi, having an environment supporting a vapor state for said plurality of precursor components; and a thermal barrier located between said liquid supply assembly and said vaporization chamber enabling preservation of a large temperature disparity between said liquid supply assembly and said proximately located vaporization chamber.

### RELATED APPLICATIONS

The instant application claims priority to Provisional U.S. Patent Application Serial No. 60/337,637 entitled “CHEMICAL VAPOR DEPOSITION (CVD) VAPORIZER” filed Dec. 4, 2001, the disclosure of which application is hereby incorporated herein by reference. The instant application is related to concurrently filed, commonly assigned, and co-pending U.S. patent application Ser. No. 13180.113C1US entitled “CHEMICAL VAPOR DEPOSITION REACTOR AND METHOD FOR UTILIZING VAPOR VORTEX”, the disclosure of which application is hereby incorporated herein by reference.

### BACKGROUND OF THE INVENTION

1. Field of the Invention

The present invention relates to methods for depositing high quality films of complex materials on substrates at high deposition rates and apparatuses for effecting such methods. The invention relates in particular to systems and methods for efficiently vaporizing precursors for subsequent reaction in a deposition chamber.

2. Statement of the Problem

CVD is a common method of depositing thin films of complex compounds, such as metal oxides, ferroelectrics, superconductors, materials with high dielectric constants, gems, etc. Existing methods of chemical vapor deposition, while providing good step coverage, generally result in relatively low integrated circuit yields when used to deposit the complex materials. In prior art CVD methods, one or more liquid or solid precursors are converted into a gaseous state. To gasify sufficient quantities of precursor at a commercially viable rate, it is typically necessary to heat the precursor. However, the precursors are typically physically unstable at the higher temperatures necessary to achieve sufficient mass transfer of the precursor from the liquid phase or solid phase to the gaseous phase. This physical instability may manifest itself in premature boiling of the precursor solvents. Consequently, precursor compounds commonly experience separation, decomposition, or precipitation. Premature separation causes undesirable, uncontrolled changes in the chemical stoichiometry of the process streams and the final product, uneven deposition of the substrate in the CVD reactor, and fouling of the CVD apparatus, necessitating costly and highly inconvenient disruptions of CVD equipment operation to clean affected equipment components. Further, particulate matter can fall down onto the wafer resulting in defective devices and low yields. In addition, because premature separation of precursor reagents generally does not occur uniformly for all components of a precursor, it also results in a disproportionate removal of selected reagents from a gas precursor causing the remaining gas precursor to include an altered stoichiometry which results ineffective chemical compositions on the surface of the wafer.

Another problem with existing CVD systems is that of incomplete gasification of precursors. Where one or more precursors fail to properly gasify in apparatus leading to the deposition chamber, the one or more precursors may be deposited on a substrate without having properly reacted with other precursors in the CVD apparatus. This is due to the growth of interdependency between certain precursors. Such improper deposition causes waste of the unreacted precursor materials and may cause malfunction of the circuit onto which such deposition takes place.

One approach to improving CVD operation is disclosed in U.S. patent application Ser. No. 09/446,226 filed Dec. 17, 1999 by Paz de Araujo et al. This application discloses a multi-stage gasification process, which process includes initially misting the liquid precursors using a venturi mist generator, at near atmospheric pressure, and then conducting low temperature gasification in a separate chamber known as a gasifier. While representing an improvement over pre-existing technology, the disclosed multi-stage CVD system proposes the use of a vaporization step that is sub-optimal and subjects the chemical to precipitation and condensation while managing the phase transitions of precursors from liquid to mist to gas.

It would be beneficial to the CVD art to provide an apparatus and a method for managing the transition of precursor materials from liquid to mist and from mist to gas in a reliable and efficient manner. A further benefit would be obtained from an apparatus and method which enable effective control of stoichiometry in a deposited thin film, which avoid the problem of premature decomposition, and which still provide the traditional advantages of CVD processes, such as good step coverage and uniform film quality. A still further benefit would be obtained from an apparatus having a design capable of being efficiently and cost-effectively manufactured.

### SOLUTION

The present invention advances the art and helps to overcome the aforementioned problems by providing a CVD vaporizer which includes a thermal insulator or thermal barrier located between fluid supply components and a vaporization chamber, thereby enabling separately controlled temperature and pressure conditions to prevail in these two apparatuses. With sufficient thermal insulation, very different temperatures may be provided in closely spaced hot and cool portions of the vaporizer. The vaporizer thereby preferably enables a liquid precursor to undergo an efficient and rapid transition from its liquid to mist to gas phases, while minimizing premature decomposition of the precursor due to undesirably warm temperatures of the precursor during its liquid or mist phases.

Where mere separation distance between a liquid supply assembly and a vaporization chamber is relied upon for thermal insulation, considerably more space would be needed to house these two portions of a vaporizer. Moreover, the increased space needed for insulation based on separation distance provides an opportunity for premature decomposition of a precursor. Providing closely spaced warm and cool regions of a vaporizer allows the conversion of liquid precursor material into more volatile phases in a closely controlled manner and close to the reaction zone. In comparison with existing systems, the vaporizer disclosed herein diminishes the distance over which misted precursor material may experience undesired, premature decomposition, solvent separation, and/or solvent precipitation.

In one embodiment, a liquid supply assembly, preferably including a liquid precursor blend in a precursor conduit and a cooling mechanism for this conduit such as a liquid cooling jacket which may be a water jacket, is located on one side of a thermal divide. Preferably, a vaporization chamber for gasifying the precursor is located on the other side of the thermal divide. A source of carrier gas, which is generally hot, is preferably located conveniently to a venturi for misting the liquid precursor blend. Keeping the liquid supply assembly cool preferably benefits the operation of the vaporizer by inhibiting premature chemical reactions among reagents in precursor fluids, inhibiting premature decomposition of the reagents, and/or preventing premature gasification of the carrier solvents. Keeping the vaporization chamber warm preferably benefits vaporizer operation by rapidly converting misted precursor droplets into a gaseous phase, in which phase precursor stoichiometry and reactions among components of the precursor blend may be more effectively controlled. Optionally, a low pressure environment may be implemented in the vaporization chamber to still further enhance evaporation of precursor mist droplets.

The placement of an effective thermal barrier between separate compartments of the vaporizer preferably enables the ambient conditions in the separate compartments of the vaporizer to be separately controlled. The controlled ambient characteristics include but are not limited to temperature, pressure, and fluid velocity. Preferably, the ambient conditions in the liquid supply assembly are controlled to maintain all components of the liquid precursor in liquid form. Similarly, the ambient conditions in the vaporization chamber are preferably controlled to maintain all components of the liquid precursor in gaseous form. Consequently, the transition between the separately controlled environments of the vaporizer preferably effects substantially simultaneous evaporation of all components of the liquid precursor, even where these components have widely divergent boiling points, vapor pressures, and/or other conditions relevant to evaporation.

The invention provides a method of providing a vapor to a deposition chamber, the method comprising: maintaining a precursor blend in liquid form; misting the precursor blend; substantially simultaneous evaporating all precursor components of the misted precursor blend; and preserving the evaporated precursor components in vapor form after the evaporating, thereby providing a vaporized precursor blend. Preferably, the maintaining comprises flowing the precursor blend through a liquid supply assembly. Preferably, the substantially simultaneously evaporating comprises evaporating the precursor components over a gasification distance of less than one inch. Preferably, the substantially simultaneously evaporating comprises evaporating the precursor components over a gasification distance of less than 0.5 inches. Preferably, the substantially simultaneously evaporating comprises evaporating the precursor components over a gasification distance of less than 0.25 inches. Preferably, the substantially simultaneously evaporating comprises evaporating the precursor components over a gasification distance of less than 0.15 inches. Preferably, the evaporating occurs within a vaporization chamber. Preferably, the maintaining comprises providing ambient conditions corresponding to a liquid state of all the precursor components. Preferably, the preserving comprises providing ambient conditions corresponding to a vapor state of all the precursor components. Preferably, the evaporating comprises providing an abrupt transition from a first set of ambient conditions supporting a misted state of all of the precursor components to a second set of ambient conditions supporting a vapor state of all the precursor components. Preferably, the abrupt transition comprises a transition distance of less than 0.5 inches. Preferably, the abrupt transition comprises a transition distance of less than 0.25 inches. Preferably, the abrupt transition comprises a transition distance of less than 0.0625 inches. Preferably, the method further comprises thermally insulating the vaporized precursor blend from the liquid precursor blend. Preferably, the method further comprises transmitting the vaporized precursor blend directly into a deposition chamber. Preferably, the method further comprises accelerating a flow rate of the liquid precursor blend proximate to the misting. Preferably, the method further comprises accelerating a flow rate of a carrier gas for misting the liquid precursor blend proximate to the misting. Preferably, the misting comprises producing droplets having a diameter of less than one micron. Preferably, the misting comprises producing droplets having an average diameter of substantially 0.5 microns. Preferably, the evaporating comprises providing an ambient temperature between 180° C. and 250° C. for the misted precursor components. Preferably, the evaporating comprises providing an ambient pressure between 2 torr and 8 torr for the misted precursor components. Preferably the method further comprises providing a first portion and a second portion of a vaporization chamber; and partially thermally isolating the regions of the vaporization chamber. Preferably, the method further comprises separately thermally controlling the first portion and the second portion of the vaporization chamber.

In another aspect, the invention provides a chemical vapor deposition (CVD) vaporizer comprising: a liquid supply assembly having an environment supporting a liquid state for a plurality of precursor components of a liquid precursor blend; a venturi operative to atomize the liquid precursor blend; a vaporization chamber, located proximate to the liquid supply assembly and the venturi, having an environment supporting a vapor state for the plurality of precursor components; and a thermal barrier located between the liquid supply assembly and the vaporization chamber enabling preservation of a substantial temperature disparity between the liquid supply assembly and the proximately located vaporization chamber. Preferably, a transition distance between a precursor liquid conduit of the liquid supply assembly and the vaporization chamber is less than 0.5 inches. Preferably, a transition distance between a precursor liquid conduit of the liquid supply assembly and the vaporization chamber is less than 0.25 inches. Preferably, a transition distance between a precursor liquid conduit of the liquid supply assembly and the vaporization chamber is less than 0.0625 inches. Preferably, the liquid supply assembly, the venturi, and the proximately located vaporization chamber cooperate to enable substantially simultaneous evaporation of all the precursor components. Preferably, the liquid supply assembly, the venturi, and the proximately located vaporization chamber provide conditions suitable for substantially simultaneously evaporating liquids having a wide range of boiling points and vapor pressures. Preferably, the liquid supply assembly comprises a precursor conduit and a water jacket for cooling the precursor conduit. Preferably, the precursor conduit comprises a restricted flow injector operative to accelerate a flow of the liquid precursor blend proximate to the venturi. Preferably, the precursor conduit comprises a restricted flow injector operative to preserve a liquid state of the liquid precursor blend prior to arrival at the venturi. Preferably, the restricted flow injector has a diameter of between 0.05 inches and 0.09 inches. Preferably, the venturi is operative to provide droplets having a diameter of less than one micron. Preferably, the venturi is operative to provide droplets having an average diameter of substantially 0.5 microns. Preferably, the vaporization chamber comprises: a first chamber portion located adjacent the liquid supply assembly; a second chamber portion located downstream along a path of precursor flow from the first chamber portion; and a thermal break located between the first chamber portion and the second chamber portion. Preferably, the thermal break is a circumferential gap in a body of the vaporization chamber. Preferably, a first heater heats the first chamber portion. Preferably, a second heater heats the second chamber portion. Preferably, the first portion and the second portion are separately thermally controllable. Preferably, a temperature inside the vaporization chamber is controlled between 180° C. and 250° C. Preferably, the pressure inside the vaporization chamber is controlled between 2 torr and 8 torr. Preferably, the thermal barrier comprises a gasket. Preferably, the thermal barrier comprises: a gasket occupying a portion of a cross-section of the thermal barrier; and an air gap having a same thickness as the gasket and occupying a remainder of the cross-section of the thermal barrier. Preferably, the gasket is made of polytetrafluoroethylene.

The above and other advantages of the present invention may be better understood from a reading of the following description of the preferred exemplary embodiments of the invention taken in conjunction with drawings in which:

### BRIEF DESCRIPTION OF THE DRAWINGS

FIG. 1 is a side sectional view of a vaporizer;

FIG. 2 is a close-up side sectional view of the venturi portion of the vaporizer of FIG. 1;

FIG. 3 is a plot of the concentration of droplet sizes in existing CVD apparatuses; and

FIG. 4 is a plot of the concentration of droplet sizes achievable employing the vaporizer of FIG. 1.

### DETAILED DESCRIPTION OF THE PREFERRED EMBODIMENT

The term “mist” as used herein is defined as fine droplets or particles of a liquid and/or solid carried by a gas. The term “mist” includes an aerosol, which is generally defined as a colloidal suspension of solid or liquid particles in a gas. The term “mist” also includes a fog, as well as other nebulized suspensions of the precursor solution in a gas. Since the above term and other terms that apply to suspensions in a gas have arisen from popular usage, the definitions are not precise, overlap, and may be used differently by different authors. In general, the term “aerosol” is intended to include all the suspensions included in the text “Aerosol Science and Technology”, by Parker C. Reist, McGraw-Hill, Inc., New York, 1983, which is incorporated by reference. The term “mist” as used herein is intended to be broader than the term “aerosol”, and includes suspensions that may not be included under the terms “aerosol” or “fog”. The term “mist” is to be distinguished from a gasified liquid, that is, a gas. It is an object of this invention to use a venturi to create a mist from a liquid precursor blend in which the resulting precursor mist droplets have an average diameter of less than one micron and preferably in the range of 0.2 microns-0.5 microns.

The terms “atomize” and “nebulize” are used interchangeably herein in their usual sense when applied to a liquid, which is to create a spray or mist, that is, to create a suspension of liquid droplets in a gas. The term “vapor” means a gas. The terms “evaporate”, “vaporize”, “vaporization”, “gasify”, and “gasification” are used interchangeably in this specification.

The term “thin film” is used herein as it is used in the integrated circuit art. Thin film means a film of less than a micron in thickness. The thin films disclosed herein are in all instances less than 0.5 microns in thickness. Preferably, the films formed by the CVD apparatus described herein are less than 300 nm thick, and most preferably are less than 200 nm thick. Films of from 20 nm to 100 nm are routinely made by the devices according to the invention. These thin films of the integrated circuit art should not be confused with so-called thin coatings or films in so-called “thin-film capacitors”. While the word “thin” is used in describing such coatings and films, these are “thin” only in respect to macroscopic materials and are generally tens and even hundreds of microns thick. The non-uniformities in such “thin” coatings are much larger than the entire thickness of a thin film as used herein; thus, the processes by which such coatings and films are made are considered by those skilled in the integrated circuit art to be incompatible with the integrated circuit art.

In a typical CVD process, reagents necessary to form a desired material are usually prepared in liquid precursor solutions, the precursors are vaporized (i.e., gasified), and the gasified reagents are fed into a deposition reactor containing a substrate, where they decompose to form a thin film of desired material on the substrate. The reagent vapors can also be formed from gases, and from solids that are heated to form a vapor by sublimation.

In the literature, there is often some inconsistent use of such terms as “reagent”, “reactant”, and “precursor”. In this application, the term “reagent” will be used to refer generally to a chemical species or its derivative that reacts in the deposition reactor to form the desired thin film. Thus, in this application, reagent can mean, for example, a metal-containing compound contained in a precursor, a vapor of the compound, or an oxidant gas. The term “precursor” refers to a particular chemical formulation used in the CVD method that comprises a reagent. For example, a precursor may be a pure reagent in solid or liquid or gaseous form. Typically, a liquid precursor is a liquid solution of one or more reagents in a solvent. Precursors may be combined to form other precursors. Herein, the original precursors used to form such a combination are precursor components; and, generally, the resulting combination is a precursor blend. Precursor liquids generally include a metal compound in a solvent, such as metal-organic precursor formulations, including alkoxides, sometimes referred to as sol-gel formulations, carboxylates, sometimes referred to as MOD formulations, and alkoxycarboxylates, sometimes referred to as EMOD formulations, and other formulations. Typically, metal-organic formulations for MOCVD comprise a metal alkyl, a metal-alkoxide, a beta-diketonate, combinations thereof, as well as many other precursor formulations. In one embodiment, a multi-metal polyalkoxide may be used. MOD formulations can be formed by reacting a carboxylic acid, such as 2-ethylhexanoic acid, with a metal or metal compound in a solvent. Solvents which may be employed in any of the above formulations include methyl ethyl ketone, isopropanol, methanol, tetrahydrofuran, xylene, n-butyl acetate, hexamethyl-disilazane (HMDS), octane, 2-methoxyethanol, and ethanol. An initiator, such as methyl ethyl ketone (MEK), may be added. A more complete list of solvents and initiators, as well as specific examples of metal compounds, are included in U.S. Pat. No. 6,056,994, issued May 2, 2000 to Paz de Araujo et al., entitled “Liquid Deposition Methods Of Fabricating Layered Superlattice Materials”, and U.S. Pat. No. 5,614,252, issued Mar. 25, 1997 to McMillan et al., entitled “Method Of Fabricating Barium Strontium Titanate”, which patents are hereby incorporated by reference to the same extent as if fully set forth herein.

A “gasified” precursor as used herein refers to gaseous forms of all the constituents previously contained in a liquid precursor, for example, vaporized reagents and vaporized solvent. The term “gasified precursor” refers to the gasified form of a single precursor or the gas phase mixture of a plurality of precursors. The terms “reactant” and “reactant gas” in this application will generally refer to a gas phase mixture containing reagents involved in the deposition reactions occurring at the substrate plate in the deposition reactor, although the mixture logically includes other chemical species, such as vaporized solvent and unreactive carrier gas.

Preferably, a liquid precursor contains a multi-metal polyalkoxide reagent, particularly to reduce the total number of liquid precursors to be misted, mixed, and gasified. Nevertheless, the use of single-metal polyalkoxide precursors is fully consistent with the method and apparatus of the invention. All polyalkoxides are also “alkoxides”. Multi-metal polyalkoxides are included within the terms “metal alkoxides” and “metal polyalkoxides”. The terms “polyalkoxide”, “metal polyalkoxide”, and “multi-metal polyalkoxide” are, therefore, used somewhat interchangeably in this application, but the meaning in a particular context is clear.

The term “premature decomposition” in this application refers to any decomposition of the reagents that does not occur at the heated substrate. Premature decomposition includes, therefore, chemical decomposition of reagents in various stages of the vaporizer and in a deposition reactor itself, if it is not at the heated substrate. Since it is known from the art of thermodynamics and chemical reaction kinetics that some premature decomposition will almost certainly inevitably occur to a slight extent even under optimum operating conditions, it is desirable to prevent “substantial premature decomposition”. Substantial premature decomposition occurs if premature decomposition causes the formation of particles of solid material on the substrate, in place of a continuous, uniform thin film of solid material. Substantial premature decomposition also occurs if premature decomposition causes fouling of the CVD apparatus that necessitates shutting down and cleaning the apparatus more frequently than once for every 100 wafers processed.

Herein, a “conduit” is a tube, pipe, or other apparatus for containing fluid flow. A conduit may contain liquid, mist, or gas flow. Herein, a “thermal barrier” is an obstacle to heat transfer between different portions of a vaporizer. A “thermal insulator” is a portion of a thermal barrier preferably including a thermally insulating solid material, although gaseous or liquid insulators may be employed. A thermal barrier may include an air gap.

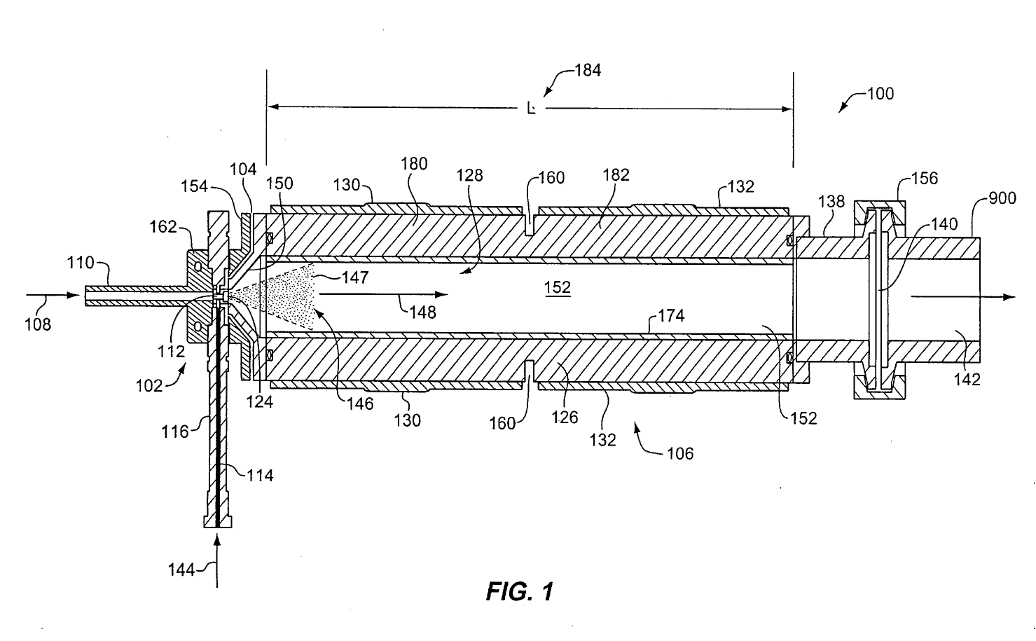

FIG. 1 is a side sectional view of vaporizer 100. In one embodiment, vaporizer 100 includes liquid supply assembly 102, thermal barrier 104, vaporization chamber 106, and chamber connector 138. Deposition chamber inlet 142 is shown connected to chamber connector 138. Deposition chamber inlet 142 preferably forms part of a deposition chamber 900 for semiconductor fabrication. Thermal barrier 104 preferably inhibits heat transfer in both directions between liquid supply assembly 102 and vaporization chamber 106. Precursor blend 144 flows throughout vaporizer 100 in different phases. Precursor blend 144 preferably includes precursor liquid blend 114, misted precursor 146, and gaseous precursor 148.

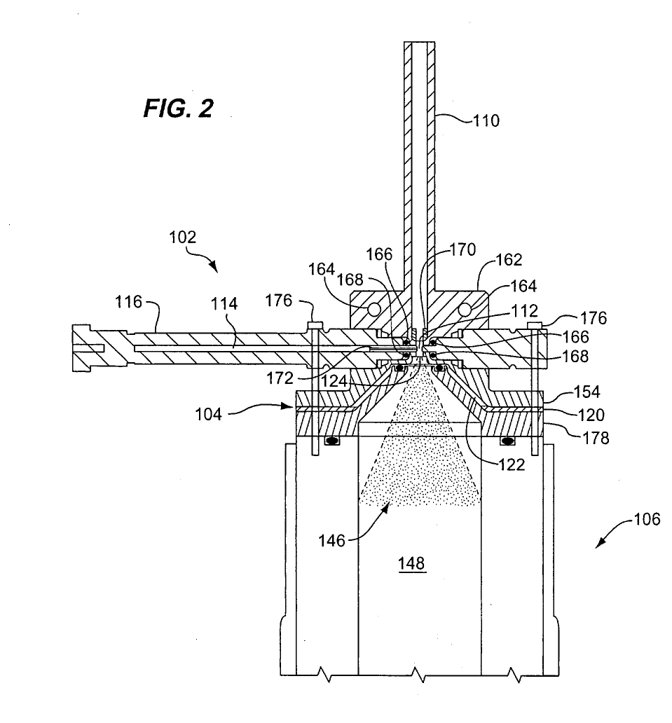

In one embodiment, liquid supply assembly 102 includes precursor conduit 116, precursor liquid blend 114, and cooling fluid jacket 162. Conduit 116 may be a tube, pipe, or other suitable container for the flow of precursor liquid blend 114, which containers are known in the art. Carrier gas conduit 110 preferably supplies carrier gas 108. Suitable conduits for carrier gas 108 are also known in the art. Venturi 112 is preferably located at an intersection of precursor conduit 116 and carrier gas conduit 110 and preferably generates mist 146 of precursor blend 144. Although only one precursor conduit 116 is shown, two or more precursor conduits may be employed to carry precursor chemicals to venturi 112 for atomization. Likewise, although only one carrier gas conduit 110 is shown, a plurality of carrier gas conduits may be employed to enable the misting of one or more precursor fluids. The features of liquid supply assembly 102 are discussed in greater detail in connection with FIG. 2. In one embodiment, thermal barrier 104 is located between liquid supply assembly 102 and vaporization chamber 106. Thermal barrier 104 is also discussed in greater detail in connection with FIG. 2.

In one embodiment, vaporization chamber 106 includes mist orifice 124 which is preferably substantially centered with respect to the cross-sectional geometry of vaporization chamber 106 (looking from left to right in the view of FIG. 1) and located near venturi 112. Vaporization chamber 106 preferably comprises chamber body 126 and interior space 128. Interior space 128 preferably includes graduated expansion region 150 near mist orifice 124 and constant diameter region 152. Constant diameter region 152 preferably has a length 184 of about 10 inches, although vaporization chambers having lengths shorter or longer than 10 inches may be employed. While two specific portions of interior space 128 of vaporization chamber 106 are discussed in connection with FIG. 2, it will be appreciated that interior space 128 could include fewer than or more than two geometrically distinctive portions.

Vaporization chamber 106 preferably includes vaporization heaters 130 and 132, which preferably follow the outside circumference of chamber body 126. Alternatively, a plurality of heaters could be employed in place of each of heaters 130 and 132, with each heater occupying only a portion of the circumference of chamber body 126. Moreover, a plurality of circumferentially arranged heaters could be employed. Thermal break 160 is preferably located between heater 130 and heater 132 to diminish conductivity between the portions 180, 182 of vaporization chamber 106 located on opposite sides of thermal break 160. Preferably, thermal break 160 is in the form of a circumferential indentation in chamber body 126, a cross-section of which recess is shown in FIG. 1. However, alternative designs for reducing conductivity between portions of vaporization chamber 106 could be employed, including the provision of insulating material, other than air, and/or the deployment of less thermally conductive metal as part of chamber body 126 in the region separating portions 180 and 182 of vaporization chamber 106.

Vaporizer 100 preferably includes chamber connector 138 located adjacent to vaporization chamber 106. Chamber connector 138 is preferably mechanically and fluidically connected to deposition chamber inlet 142 across chamber connector interface 140. NW ring clamp 156 is preferably employed to clamp together chamber connector 138 and deposition chamber inlet 142 at connected interface 140. However, other types of fastening equipment could be employed.

Vaporization chamber 106 is preferably coupled to pumping equipment (not shown) for providing a low pressure environment in interior space 128 of vaporization chamber 106. In one embodiment, a liner 174 may be disposed on the interior circumference of chamber body 126. Liner 174 is preferably removable and is preferably made of aluminum.

FIG. 2 is a close-up side sectional view of the venturi 112 portion of vaporizer 100 shown in FIG. 1. Thermal barrier 104 is shown located between chamber attachment plate 178 and external profile plate 154. In one embodiment, thermal barrier 104 includes thermal spacer 120 and thermal barrier gap 122. Thermal spacer 120 is preferably a 0.040 inch thick polytetrafluoroethylene gasket. However, thermal spacer 120 may be made of other preferably thermally insulating materials and may have a thickness less than or greater than 0.040 inches. Thermal barrier gap 122 is preferably a 0.040 inch thick air gap occupying the space between chamber attachment plate 178 and external profile plate 154 not occupied by thermal spacer 120. However, as with thermal spacer 120, the thickness of thermal barrier gap 122 may be less than or greater than 0.040 inches.

In one embodiment, a plurality of screws 176, preferably made of ceramic or plastic, connects liquid supply assembly 102 to vaporization chamber 106. Preferably, O-rings 166 and 168 are located to prevent unwanted contact between liquid conduit 116 and cooling fluid jacket 162.

In one embodiment, cooling fluid jacket 162 is above (in the view of FIG. 2) and adjacent to precursor conduit 116. Cooling fluid jacket 162 is preferably in conductive thermal contact with precursor conduit 116. Cooling fluid jacket 162 preferably includes a plurality of fluid ports 164 which provide access to a cooling fluid conduit (not shown) within cooling fluid jacket 162.

In one embodiment, precursor conduit 116 includes restricted flow injector 172. Restricted flow injector 172 preferably has an internal diameter of between 0.05 inches and 0.09 inches, and more preferably of about 0.07 inches. The deployment of restricted flow injector 172 preferably maintains the pressure of precursor liquid blend 114 in precursor conduit 116. Restricted flow injector 172 preferably terminates near venturi 112. In one embodiment, carrier gas conduit 110 includes gas flow restriction 170, which is located at an end of carrier gas conduit 110 nearest venturi 112. Gas flow restriction 170 preferably provides a gas flow diameter of between 0.020 inches and 0.030 inches, and more preferably of 0.025 inches.

The operation of the instant vaporizer is now discussed with reference to FIGS. 1-4. In one embodiment, precursor liquid blend 114, while within precursor conduit 116, is in an environment having a temperature of about 20° C. and a pressure slightly exceeding atmospheric pressure, or about 800 torr. Precursor liquid blend 114 is preferably directed along precursor conduit 116 to restricted flow injector 172 located at an end of precursor conduit 116 nearest venturi 112. Preferably, restricted flow injector 172 prevents a premature decline in the static pressure of precursor liquid blend 114 within precursor conduit 116, thereby beneficially preserving a liquid state of precursor liquid blend 114 until atomization at venturi 112. Preferably, the flow velocity of precursor liquid blend 114 is increased by the reduced flow diameter provided by restricted flow injector 172 just before encountering venturi 112, thereby enhancing the atomizing operation of venturi 112.

In one embodiment, carrier gas 108, within carrier gas conduit 110, is in an environment having a temperature of about 200° C. and a pressure of about 15 P.S.I. (Pounds per Square Inch). Carrier gas 108 preferably has a flow rate of about one liter per minute. Carrier gas 108 is preferably directed along conduit 110 to gas flow restriction 170 at the end of conduit 110 nearest venturi 112. Gas flow restriction 170 preferably increases the flow velocity of carrier gas 108, thereby enhancing the operation of venturi 112.

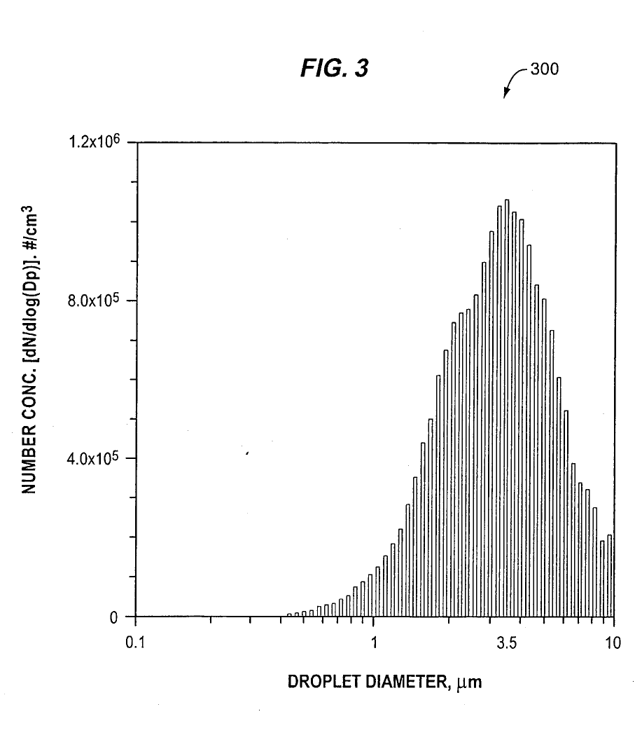

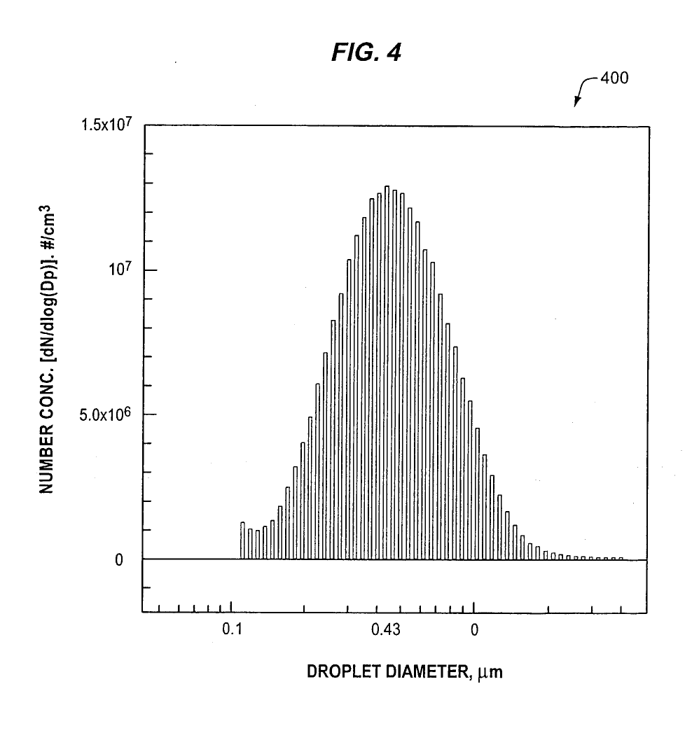

In one embodiment, liquid precursor blend is atomized at venturi 112, and the resulting precursor mist 146 is then directed into vaporization chamber 106. The atomizing operation of venturi 112 is preferably aided by the velocities of liquid precursor blend 114 (which velocity is increased by restricted flow injector 172) and of carrier gas 108 (the velocity of which is increased by gas flow restrictor 170). This atomizing operation is preferably further aided by the transition from a relatively high pressure region within precursor conduit 110 to the low pressure region of vaporization chamber 106 (discussed in greater detail below). These factors preferably combine to enable venturi 112 to generate droplets having average diameters of less than one micron and more preferably in the range 0.2 microns-0.5 microns. A plot 400 of the range of droplet diameters obtained employing vaporizer 100 is shown in FIG. 4. A plot 300 of prior art droplet diameter distribution is shown in FIG. 3. It may be seen that the average droplet diameter provided by vaporizer 100 is considerably smaller than that provided by the prior art.

Precursor mist 146 generated by venturi 112 is preferably directed through orifice 124 into graduated expansion region 150 of vaporization chamber 106, leading to a cone-shaped precursor mist 146 field, which field is shaded in FIGS. 1 and 2. Graduated expansion region 150 is preferably shaped to enhance a natural pattern of expansion of precursor mist 146 into vaporization chamber 106, thereby aiding the gasification of precursor mist 146. As the droplets evaporate, misted precursor 146 becomes precursor gas 148.

The gasification of droplets in misted precursor 146 is preferably aided by a combination of the low pressure and high temperature environment of vaporization chamber 106 and the high surface-area-to-volume ratio of droplets in mist 146. Interior space 128 of vaporization chamber 106 preferably has an ambient pressure of between 2 torr and 8 torr and more preferably of 5 torr. Interior space 128 preferably has an ambient temperature between 180° C. and 250° C., more preferably between 220° C. and 240° C., and most preferably of about 230° C. Since the ratio of surface area to volume increases with decreasing droplet diameter, the previously discussed sub-micron droplet diameters provided by venturi 112 enhance droplet evaporation over and above the effects provided by the ambient conditions of vaporization chamber 106.

Precursor conduit 116 preferably provides a temperature and pressure combination which supports a liquid state of all precursor components within precursor blend 144. Similarly, vaporization chamber 106 preferably provides a temperature and pressure combination which supports a gaseous state of all the precursor components. Moreover, the transition between these environments is preferably sufficiently abrupt to enable substantially simultaneous gasification of all components of precursor blend 144, even where such components have a wide range of boiling points and partial pressures. In this disclosure, the “abrupt” transition between environments discussed above corresponds to a transition distance between the upper end of precursor conduit 116 and the right side of mist orifice 124, which transition distance is preferably less than one inch, more preferably less than 0.5 inches, still more preferably less than 0.25 inches, still more preferably less than 0.125 inches, and still more preferably less than 0.0625 inches. Preferably, the substantially simultaneous gasification enabled by the above-described “abrupt transition” corresponds to a gasification distance into vaporization chamber 106, from mist orifice 124 to gasification point 147, over which substantially complete gasification of liquid precursor blend 114 occurs, which gasification distance is preferably less than one inch, more preferably less than 0.5 inches, still more preferably less than 0.375 inches, still more preferably less than 0.25 inches, and still more preferably less than 0.15 inches.

Such substantial simultaneity provides a significant advantage over existing systems in which conditions may favor gasification of one precursor component but not another. In such existing systems, inconsistent degrees of gasification of the precursor components can lead to improper precursor component concentrations near a substrate. The conversion of precursor blend 144 from liquid to mist to gas phases within a short time frame, within a small geometric space, and in close proximity to deposition chamber 900 preferably prevents undesired chemical reaction, condensation, precipitation, and premature decomposition of precursor materials which may arise when precursor materials co-exist in mist form for a prolonged period.

In one embodiment, precursor mist 146 is converted into precursor gas 148 while moving from left to right (in the view of FIG. 1) through low pressure, heated vaporization chamber 106. Thereafter, precursor gas 148 is preferably directed through chamber connector 138 and deposition chamber inlet 142 for deposition onto a substrate (not shown) within deposition chamber 900 coupled to deposition chamber inlet 142.

Temperature control of vaporization chamber 106 is preferably aided by the provision of two heaters 130, 132 attached to two separate portions 180, 182 of vaporization chamber 106 separated by thermal break 160. Differing thermal factors operating on different parts of vaporization chamber 106 could lead to temperature variation within chamber 106, where a single heater or other form of thermal control is employed for all of chamber 106. The provision of thermal break 160 separating first chamber portion 180 and second chamber portion 182 preferably enables independent thermal control of these portions. Thus, heaters 130 and 132 may operate at different power levels to compensate for variation in thermal factors present in their respective portions of chamber 106. While the above discussion is directed to an embodiment of vaporization chamber 106 having two separately thermally controlled portions 180, 182, the principles disclosed herein may be easily extended to embodiments including three or more such thermally isolated vaporization chamber portions.

There have been described what are, at present, considered to be the preferred embodiments of the invention. It will be understood that the invention can be embodied in other specific forms without departing from its spirit or essential characteristics. For instance, each of the inventive features mentioned above may be combined with one or more of the other inventive features. That is, while all possible combinations of the inventive features have not been specifically described, so as the disclosure does not become unreasonably long, it should be understood that many other combinations of the features may be made. The present embodiments are, therefore, to be considered as illustrative and not restrictive. The scope of the invention is indicated by the appended claims.

We claim:

1. A method of providing a vapor to a deposition chamber, the method comprising:
maintaining a precursor blend in liquid form;
misting said precursor blend;
substantially simultaneously evaporating all precursor components of said misted precursor blend; and
preserving said evaporated precursor components in vapor form after said evaporating, thereby providing a vaporized precursor blend.

2. The method of claim 1 wherein said maintaining comprises flowing said precursor blend through a liquid supply assembly.

3. The method of claim 1 wherein said substantially simultaneously evaporating comprises evaporating said precursor components over a gasification distance of less than one inch.

4. The method of claim 1 wherein said substantially simultaneously evaporating comprises evaporating said precursor components over a gasification distance of less than 0.5 inches.

5. The method of claim 1 wherein said substantially simultaneously evaporating comprises evaporating said precursor components over a gasification distance of less than 0.25 inches.

6. The method of claim 1 wherein said substantially simultaneously evaporating comprises evaporating said precursor components over a gasification distance of less than 0.15 inches.

7. The method of claim 1 wherein said evaporating occurs within a vaporization chamber.

8. The method of claim 1 wherein said maintaining comprises providing ambient conditions corresponding to a liquid state of all said precursor components.

9. The method of claim 1 wherein said preserving comprises providing ambient conditions corresponding to a vapor state of all said precursor components.

10. The method of claim 1 wherein said evaporating comprises providing an abrupt transition from a first set of ambient conditions supporting a misted state of all of said precursor components to a second set of ambient conditions supporting a vapor state of all said precursor components.

11. The method of claim 1 wherein said abrupt transition comprises a transition distance of less than 0.5 inches.

12. The method of claim 1 wherein said abrupt transition comprises a transition distance of less than 0.25 inches.

13. The method of claim 1 wherein said abrupt transition comprises a transition distance of less than 0.0625 inches.

14. The method of claim 1 further comprising thermally insulating said vaporized precursor blend from said liquid precursor blend.

15. The method of claim 1 further comprising transmitting said vaporized precursor blend directly into a deposition chamber.

16. The method of claim 1 further comprising accelerating a flow rate of said liquid precursor blend proximate to said misting.

17. The method of claim 1 further comprising accelerating a flow rate of a carrier gas for misting said liquid precursor blend proximate to said misting.

18. The method of claim 1 wherein said misting comprises producing droplets having a diameter of less than one micron.

19. The method of clam 1 wherein said misting comprises producing droplets having an average diameter of substantially 0.5 microns.

20. The method of claim 1 wherein said evaporating comprises providing an ambient temperature between 180° C. and 250° C. for said misted precursor components.

21. The method of claim 1 wherein said evaporating comprises providing an ambient pressure between 2 torr and 8 torr for said misted precursor components.

22. The method of claim 1 further comprising:
providing a first portion and a second portion of a vaporization chamber; and
partially thermally isolating said regions of said vaporization chamber.

23. The method of claim 22 further comprising separately thermally controlling said first portion and said second portion of said vaporization chamber.

24. A chemical vapor deposition (CVD) vaporizer comprising:
a liquid supply assembly having an environment supporting a liquid state for a plurality of precursor components of a liquid precursor blend;
a venturi operative to atomize said liquid precursor blend;
a vaporization chamber, located proximate to said liquid supply assembly and said venturi, having an environment supporting a vapor state for said plurality of precursor components; and
a thermal barrier located between said liquid supply assembly and said vaporization chamber enabling preservation of a substantial temperature disparity between said liquid supply assembly and said proximately located vaporization chamber.

25. A CVD vaporizer as in claim 24 wherein a transition distance between a precursor liquid conduit of said liquid supply assembly and said vaporization chamber is less than 0.5 inches.

26. A CVD vaporizer as in claim 24 wherein a transition distance between a precursor liquid conduit of said liquid supply assembly and said vaporization chamber is less than 0.25 inches.

27. A CVD vaporizer as in claim 24 wherein a transition distance between a precursor liquid conduit of said liquid supply assembly and said vaporization chamber is less than 0.0625 inches.

28. A CVD vaporizer as in claim 24 wherein said liquid supply assembly, said venturi, and said proximately located vaporization chamber cooperate to enable substantially simultaneous evaporation of all said precursor components.

29. A CVD vaporizer as in claim 24 wherein said liquid supply assembly, said venturi, and said proximately located vaporization chamber provide conditions suitable for substantially simultaneously evaporating liquids having a wide range of boiling points and vapor pressures.

30. A CVD vaporizer as in claim 24 wherein said liquid supply assembly comprises a precursor conduit and a water jacket for cooling said precursor conduit.

31. A CVD vaporizer as in claim 30 wherein said precursor conduit comprises a restricted flow injector operative to accelerate a flow of said liquid precursor blend proximate to said venturi.

32. A CVD vaporizer as in claim 30 wherein said precursor conduit comprises a restricted flow injector operative to preserve a liquid state of said liquid precursor blend prior to arrival at said venturi.

33. A CVD vaporizer as in claim 31 wherein said restricted flow injector has a diameter of between 0.05 inches and 0.09 inches.

34. A CVD vaporizer as in claim 24 wherein said venturi is operative to provide droplets having a diameter of less than one micron.

35. A CVD vaporizer as in claim 24 wherein said venturi is operative to provide droplets having an average diameter of substantially 0.5 microns.

36. A CVD vaporizer as in claim 24 wherein said vaporization chamber comprises:
a first chamber portion located adjacent said liquid supply assembly;
a second chamber portion located downstream along a path of precursor flow from said first chamber portion; and
a thermal break located between said first chamber portion and said second chamber portion.

37. A CVD vaporizer as in claim 36 wherein said thermal break is a circumferential gap in a body of said vaporization chamber.

38. A CVD vaporizer as in claim 36 wherein a first heater heats said first chamber portion.

39. A CVD vaporizer as in claim 36 wherein a second heater heats said second chamber portion.

40. A CVD vaporizer as in claim 36 wherein said first portion and said second portion are separately thermally controllable.

41. A CVD vaporizer as in claim 24 wherein a temperature inside said vaporization chamber is controlled between 180° C. and 250° C.

42. A CVD vaporizer as in claim 24 wherein the pressure inside said vaporization chamber is controlled between 2 torr and 8 torr.

43. A CVD vaporizer as in claim 24 wherein said thermal barrier comprises a gasket.

44. A CVD vaporizer as in claim 24 wherein said thermal barrier comprises:
a gasket occupying a portion of a cross-section of said thermal barrier; and
an air gap having a same thickness as said gasket and occupying a remainder of said cross-section of said thermal barrier.

45. A CVD vaporizer as in claim 44 wherein said gasket is made of polytetrafluoroethylene.
